(19) United States
(12) Patent Application Publication
(10) Pub. No.: US 2026/0299430 A1
(43) Pub. Date: Oct. 1, 2026

(54) OPTICAL SYSTEM INCLUDING OPTICAL FILTER AND CORRESPONDING METHOD

(71) Applicant: Taiwan Semiconductor Manufacturing Co., Ltd., Hsinchu (TW)

(72) Inventors: Hao-Ming CHANG, Hsinchu (TW); Chun-Lang CHEN, Hsinchu (TW)

(73) Assignee: Taiwan Semiconductor Manufacturing Co., Ltd., Hsinchu (TW)

(21) Appl. No.: 19/091,549

(22) Filed: Mar. 26, 2025

(51) Int. Cl. G03F 7/00; G02B 5/20; G02B 7/00; G03F 7/20

(52) U.S. Cl. CPC G03F 7/70308; G02B 5/20; G02B 7/006; G03F 7/2039; G03F 7/70191; G03F 7/70316; G03F 7/70358; G03F 7/70525; G03F 7/7085; G03F 7/70958

(57) ABSTRACT

An optical filter assembly for an optical system includes a filter body. The filter body includes a mesh defining a plurality of cells. The filter body includes a filter material positioned in the cells and configured to pass light from a light source to a target. The optical filter assembly includes a frame configured to hold the filter body.

### BACKGROUND

Optical filters, spanning from X-ray to infrared (IR) wavelengths, are components in a wide range of scientific, medical, and industrial applications. The primary function is to selectively transmit or block certain wavelengths of light while allowing others to pass through. This capability can enhance the performance and accuracy of various optical systems.

Challenges can arise from the optical filters based on material selection, durability and stability. Different materials are called for to effectively filter different wavelength ranges. For instance, materials that are transparent to IR might be opaque to visible light. Finding suitable materials that can withstand high radiation levels in applications or maintain performance across broad temperature ranges in IR applications is challenging. Besides, for those used in harsh environments like industrial settings, it is beneficial to be durable and stable over time. It is beneficial that they resist degradation due to exposure to high-energy radiation, temperature fluctuations, and physical impact.

All of the subject matter discussed in the Background section is not necessarily prior art and should not be assumed to be prior art merely as a result of its discussion in the Background section. Along these lines, any recognition of problems in the prior art discussed in the Background section or associated with such subject matter should not be treated as prior art unless expressly stated to be prior art. Instead, the discussion of any subject matter in the Background section should be treated as part of the inventor's approach to the particular problem, which, in and of itself, may also be inventive.

### BRIEF DESCRIPTION OF THE DRAWINGS

FIG. 1 is a block diagram of an optical system, in accordance with some embodiments.

FIGS. 2A-2D are illustrations of frames for an optical filter assembly, in accordance with some embodiments.

FIGS. 3A-3D are illustrations of filter meshes of different shapes having honeycomb shaped cells, in accordance with some embodiments.

FIGS. 4A-4B are illustrations of filter meshes of different shapes having rectangular cells, in accordance with some embodiments.

FIGS. 5A-5B are illustrations of filter meshes of different shapes having triangular cells, in accordance with some embodiments.

FIG. 6 is an illustration of a filter mesh including concentric circles, in accordance with some embodiments.

FIGS. 7A-7B are cross-sectional view of filter bodies, in accordance with some embodiments.

FIG. 8 is a cross-sectional view of a filter body, in accordance with some embodiments.

FIGS. 9A-9H are cross-sectional views of a filter body at various stages of processing, in accordance with some embodiments.

FIG. 10 is a block diagram of an extreme ultraviolet (EUV) photolithography system including an optical filter assembly, in accordance with some embodiments.

FIG. 11 is a simplified illustration of an extreme ultraviolet (EUV) photolithography system including an optical filter assembly, in accordance with some embodiments.

FIG. 12 is a simplified block diagram of an x-ray system, in accordance with some embodiments.

FIG. 13 is a simplified block diagram of an optical system, in accordance with some embodiments.

FIG. 14 is a simplified block diagram of an x-ray system, in accordance with some embodiments.

FIG. 15A, is an illustration of sensing the intensity of light passed through an optical filter, in accordance with some embodiments.

FIG. 15B is a graph associated with the light of FIG. 15A, in accordance with some embodiments.

FIG. 16A, is an illustration of sensing the pressure differential on either side of an optical filter, in accordance with some embodiments.

FIG. 16B is a graph associated with the pressure differential of FIG. 16A, in accordance with some embodiments.

FIG. 17A, is an illustration of sensing the intensity of light passed through an optical filter, in accordance with some embodiments.

FIG. 17B is a graph associated with the light of FIG. 17A, in accordance with some embodiments.

FIG. 18 is a flow diagram of a method for operating an optical system, in accordance with some embodiments.

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following description, certain specific details are set forth in order to provide a thorough understanding of various embodiments of the disclosure. However, one skilled in the art will understand that the disclosure may be practiced without these specific details. In other instances, well-known structures associated with electronic components and fabrication techniques have not been described in detail to avoid unnecessarily obscuring the descriptions of the embodiments of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

The use of ordinals such as first, second and third does not necessarily imply a ranked sense of order, but rather may only distinguish between multiple instances of an act or structure.

Reference throughout this specification to “some embodiments” or “an embodiment” means that a particular feature, structure or characteristic described in connection with the embodiment is included in at least some embodiments. Thus, the appearances of the phrases “in some embodiments” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

As used in this specification, “light” generally refers to electromagnetic radiation of any wavelength, except where a particular band or wavelength is specified. Accordingly, unless specified otherwise, “light” refers to x-ray radiation, EUV radiation, ultraviolet (UV) radiation, visible radiation, infrared radiation, or other bands, wavelengths, or categories of electromagnetic radiation. Furthermore, as used herein, “optical systems” can include any system that receives/generates and utilizes electromagnetic radiation.

Embodiments of the present disclosure provide an optical filter assembly for optical systems. The optical filter assembly includes an optical filter body with a mesh including wire portions defining cells of material transparent to a desired range of wavelengths of light for the optical system. The filter body and corresponding mesh can be formed via thin film process technologies including e-beam lithography or photolithography on a substrate and corresponding material deposition, and etching processes. Due to the presence of the mesh portions, the filter body is much more robust than filter structures that do not include such a mesh. Furthermore, the presence of the mesh enables the optical filter body to be very thin while maintaining high durability with respect to tensile forces, compressive forces, impact forces, and other types of forces or environmental conditions that could otherwise damage such a thin optical filter body. The filter assembly includes a frame of a highly robust material. The frame holds the filter within an optical system. The frame further adds to the durability and strength of the filter assembly.

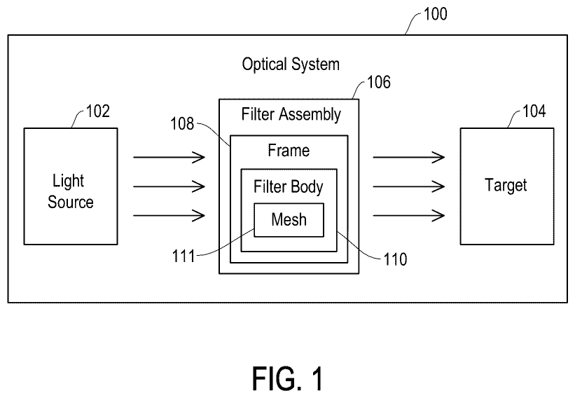

FIG. 1 is a block diagram of an optical system 100, in accordance with some embodiments. The optical system 100 includes a light source 102, a target 104, and an optical filter assembly 106. As will be set forth in more detail below, the optical filter assembly 106 enables passing desired bands of light while also retaining high stability and durability.

The light source 102 of the optical system 100 generates light to be utilized by the optical system 100. In some embodiments, the light source 102 includes a system, component, or device that generates light (i.e., electromagnetic radiation) for utilization by the optical system 100. In some embodiments, the generated light can include a broad range of wavelengths including wavelengths to be utilized for the intended purpose of the optical system 100 and wavelengths that are not to be utilized for the intended purpose of the optical system 100.

The filter assembly 106 includes a frame 108 and a filter body 110. The frame 108 is configured to hold the filter body 110 within the optical system 100. The filter body 110 is configured to receive light and to filter out undesired bands or wavelengths of light and to pass desired or selected bands or wavelengths of light. Further details regarding the filter assembly 106 are provided below.

The optical system 100 includes a target 104, in accordance with some embodiments. The target 104 is a system, device, or component that receives light from the light source 102 and processes the light in some way, reflects the light, or is modified by the light. Various types of targets 104 can be utilized based on the type of the optical system 100.

In some embodiments, the optical system 100 is a photolithography system. The light source 102 generates light for a photolithography process. In this case, the target 104 is a photolithography reticle or another optical component of the photolithography system. The light is passed to the photolithography reticle and either reflected or transmitted onto a wafer in order to pass a pattern of the reticle onto a photoresist layer on the wafer. In the example of a photolithography system, the filter assembly 106 is configured to pass a narrowband of wavelengths for the photolithography process. The light source 102 may initially generate a spectrum of wavelengths of light including the band or wavelength specified for the photolithography process. The filter body 110 passes light having the desired wavelength and filters out light having wavelengths outside the specification of the photolithography process.

In some embodiments, the optical system 100 is an x-ray system. The x-ray system can include an x-ray crystallography system that utilizes x-rays to analyze the crystal structure of the target 104. In this case, the target 104 can include a thin film, a semiconductor material, a mineral, or other types of materials for which it would be beneficial to determine the crystal structure. In some embodiments, the x-ray system includes a medical imaging system and the target is a human body or an x-ray sensitive material positioned adjacent to the human body. The light source 102 is an x-ray source that generates x-rays. The light source 102 may generate a relatively broad spectrum of wavelengths of x-rays, as well as wavelengths of light outside the x-ray spectrum. The filter body 110 passes x-rays having wavelengths within the specification of the x-ray system and filters out x-rays or other types of light having wavelengths that fall outside of the specifications of the x-ray system.

In some embodiments, the optical system 100 utilizes ultraviolet light. In these cases, the target 104 is a component or system that processes or is modified by the ultraviolet light. The filter body 110 receives the light generated by the light source 102, passes ultraviolet light that falls within a range of wavelengths specified for the ultraviolet system, and filters out light having wavelengths that fall outside the desired or specified range.

In some embodiments, the optical system 100 utilizes visible light. In these cases, the target 104 is a component or system that processes or is modified by the visible light. The filter body 110 receives the light generated by the light source 102, passes visible light that falls within a range of wavelengths specified for the visible light system, and filters out light having wavelengths that fall outside the desired or specified range.

In some embodiments, the optical system 100 utilizes infrared light. In these cases, the target 104 is a component or system that processes or is modified by the infrared light. The filter body 110 receives the light generated by the light source 102, passes infrared light that falls within a range of wavelengths specified for the infrared light system, and filters out light having wavelengths that fall outside the desired or specified range.

In some embodiments, the filter body 110 is made up primarily of a filter material or materials that is substantially transparent to the band of light to be utilized by the optical system 100, in accordance with the particular application of the optical system 100. The filter material is substantially opaque (i.e., absorbs or reflects) to wavelengths of light that fall outside the band of wavelengths specified for the particular application.

In the example of an x-ray system, in some embodiments the filter material includes beryllium that transmits x-rays and blocks visible in ultraviolet light. In some embodiments, the filter material includes aluminum utilized to filter out lower energy x-rays for medical imaging. Other materials and compounds can be utilized for the filter material without departing from the scope of the present disclosure.

In the example of an EUV photolithography system, in some embodiments the filter material includes zirconium. In some embodiments, the filter material includes molybdenum and silicon. Other materials and compounds can be utilized for the filter material without departing from the scope of the present disclosure.

In the example of an ultraviolet light system, in some embodiments the filter material includes fused silica that transmits ultraviolet light while blocking visible light and infrared light. In some embodiments, the filter material includes zinc sulfide that is highly transparent in the ultraviolet range. In some embodiments, the filter material includes calcium fluoride utilized for the ultraviolet applications, including Excimer laser systems. Other materials and compounds can be utilized for the filter material without departing from the scope of the present disclosure.

In the example of a visible light system, in some embodiments the filter material includes a dielectric bandpass material that only allows a specific range of wavelengths the pastor and blocks others, such as for specific laser light wavelength applications. In some embodiments, the filter material diachronic filter material that reflects some wavelengths of light while transmitting others, for example, in fluorescence microscopy. In some embodiments, the filter material includes a neutral density filter material such as a metal coating of chromium that reduces the intensity of all wavelengths equally, such as for managing exposure and photography applications. Other materials and compounds can be utilized for the filter material without departing from the scope of the present disclosure.

In the example of an infrared light system, in some embodiments the filter material includes in the infrared range and is used in thermal imaging. In some embodiments, the filter material includes silicon that is highly transmissive in near infrared wavelengths. In some embodiments, the filter material includes germanium, silicon, sapphire, or shall saw genocides utilized the long past filters to block shorter wavelengths and allow light of longer wavelengths the past, such as an 800 nm long pass filter that blocks visible light and passes near infrared light. Other materials and compounds can be utilized for the filter material without departing from the scope of the present disclosure.

The filter body 110 includes a mesh 111. The mesh 111 is a material embedded in the filter body that defines windows or cells of the filter material. The material of the mesh is described herein as “wires”. As used herein, “wires” refers to the materials and structures that define the cells or windows of the filter material. The material of the mesh 111 is selected to add strength to the filter body 110. A thin filter body formed by thin film processes may be relatively susceptible to damage or breaking based on tensile forces, compressive forces, impact forces, changes in temperature, or other factors. The presence of the mesh 111 within the filter body 110 strengthens the filter body 110 and enables the use of thin film technologies to form the filter body while maintaining robustness against breakage or other damage. In some embodiments, the thickness of the filter body 110 is less than 1 μm. The presence of the mesh 111 within the filter body 110 enables the filter body 110 to be resistant to damage even that such small thicknesses.

In some embodiments, the filter body is utilized an x-ray system and the material of the mesh 111 is silicon oxide, silicon nitride, or other suitable materials. In some embodiments, the filter body is utilized in an EUV photolithography system and the material of the mesh 111 is silicon, molybdenum, zirconium, silicon oxide, silicon nitride, carbon nanotubes, or other suitable materials. In some embodiments, the filter body 110 is utilized in an ultraviolet system and the mesh 111 is silicon oxide, calcium fluoride, manganese fluoride, or other suitable materials. In some embodiments, the filter body 110 is utilized in a visible light system and the mesh 111 is silicon oxide, polycarbonate, or other suitable materials. In some embodiments, the filter body 110 is utilized. In an infrared system and the mesh includes silicon oxide, germanium, zirconium selenide, or other suitable materials.

As described previously, the filter assembly 106 includes a frame 108. The frame holds the filter body 110. In some embodiments, the frame 108 has a shape based on the desired shape of the filter body 110 that will be held by the frame 108. In some embodiments, the frame 108 is rectangular, circular, elliptical, or of other suitable shapes depending on the application. In some embodiments, the frame includes anodized aluminum A5052, stainless steel, SuS304, SUS316L, or other suitable materials. The material of the frame 108 is selected to be highly durable within the selected application of the filter assembly 106.

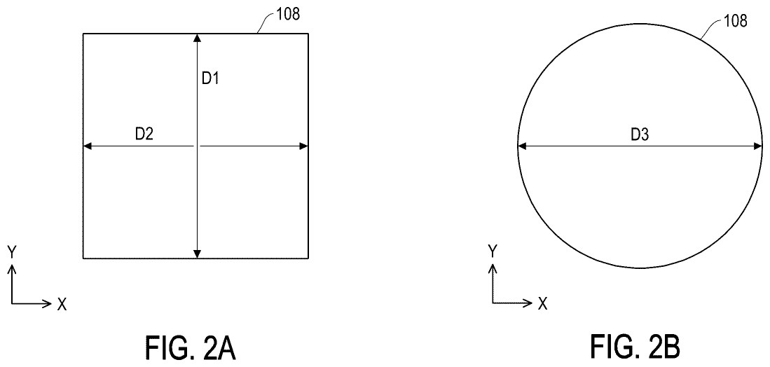

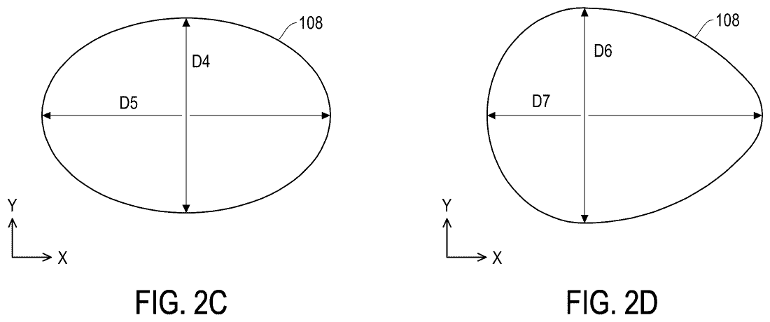

FIGS. 2A-2D illustrate frames 108 having various shapes, in accordance with some embodiments. The frames 108 of FIGS. 2A-2D are examples of the frame 108 of FIG. 1. The axes X and Y denote lateral dimensions. In other figures, the vertical dimension (thickness) is denoted by the axis Z, but is not shown in FIGS. 2A-2D.

In FIG. 2A, the frame 108a is rectangular, in accordance with some embodiments. The frame 108a has a first lateral dimension D1 and a second lateral dimension D2. The dimensions D1 and D2 are between 1 cm and 30 cm. In some embodiments, the dimensions D1 and D2 are equal to each other (square). In some embodiments, the dimensions D1 and D2 are different than each other. In some embodiments, the vertical thickness of the frame 108a is less than 1 μm. Other dimensions can be utilized without departing from the scope of the present disclosure.

In FIG. 2B, the frame 108b is circular, in accordance with some embodiments. The frame 108b has a diameter dimension D3. D3 is between 1 cm and 30 cm. The frame 108b has a vertical thickness less than 1 μm. Other dimensions can be utilized without departing from the scope of the present disclosure.

In FIG. 2C, the frame 108c is elliptical and symmetrical, in accordance with some embodiments. The frame 108c has a minor axis of dimension D4 and a major axis of dimension D5. The dimensions D5 is between 1 cm and 30 cm. The ratio of D5/D4 is greater than 1.02. Other dimensions can be utilized without departing from the scope of the present disclosure.

In FIG. 2D, the frame 108d is elliptical and asymmetrical, in accordance with some embodiments. The frame 108d has a minor axis of dimension D6 and a major axis of dimension D7. The dimension D7 is between 1 cm and 30 cm. The ratio of D5/D4 is greater than 0.5. Other dimensions can be utilized without departing from the scope of the present disclosure.

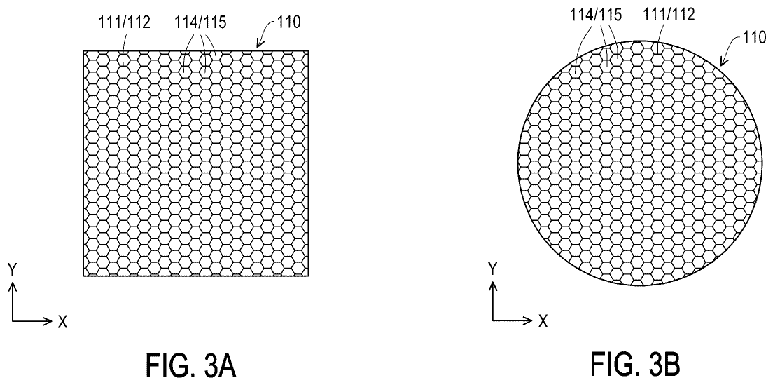

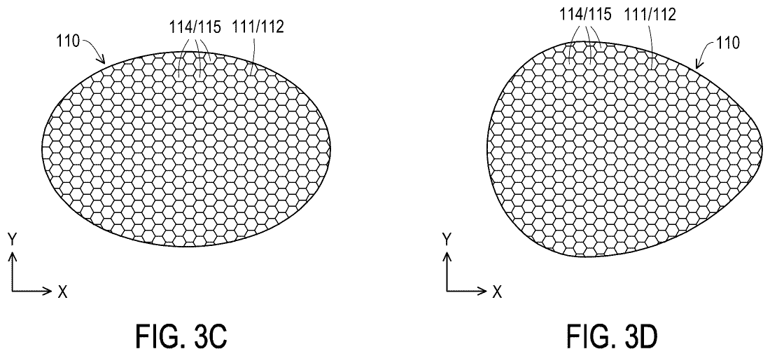

FIGS. 3A-3D illustrate filter bodies 110 having various shapes, in accordance with some embodiments. Each of the filter bodies 110 have a mesh 111 of a honeycomb shape. In other words, the mesh 111 defines cells 114 (or windows) having a honeycomb or hexagonal shape. The mesh 111 is made up of wires 112 that collectively make up the mesh. Though not shown in FIGS. 3A-3D, the cells 114 are filled with the filter material, as described previously. In some embodiments, the width of each honeycomb cell 114 is between 0.1 μm and 100 μm, though other dimensions can be utilized without departing from the scope of the present disclosure. The honeycomb pattern provides excellent mechanical strength and uniform stress distribution. The honeycomb pattern also allows for efficient packing in high surface area.

In FIG. 3A, the filter body 110 has an overall rectangular shape configured to be held or received by the rectangular frame 108 of FIG. 2A. In FIG. 3B, the filter body 110 has an overall circular shape configured to be held or received by the circular frame 108 of FIG. 2B. In FIG. 3C, filter body 110 has a symmetrical elliptical shape configured to be held or received by the elliptical frame 108 of FIG. 2C. In FIG. 3D, filter body 110 has an asymmetrical elliptical shape configured to be held or received by the asymmetrical elliptical frame 108 of FIG. 2D. Other filter body shapes can be utilized without departing from the scope of the present disclosure.

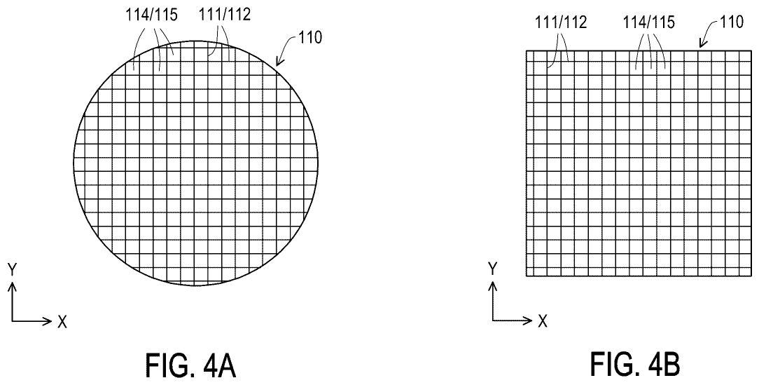

FIGS. 4A-4B illustrate filter bodies 110 having various shapes, in accordance with some embodiments. Each of the filter bodies 110 has a mesh 111 of a rectangular shape. In other words, the mesh 111 defines cells 114 (or windows) having a rectangular shape. The cells are evenly spaced. Though not shown in FIGS. 4A-4B the cells 114 are filled with the filter material, as described previously. In some embodiments, the width of each rectangular cell 114 is between 0.1 μm and 100 μm, though other dimensions can be utilized without departing from the scope of the present disclosure. The rectangular pattern is simple to manufacture and provides a good balance between the chemical support and open area.

In FIG. 4A, the filter body 110 has an overall rectangular shape configured to be held or received by the rectangular frame 108 of FIG. 2A. In FIG. 4B, the filter body 110 has an overall circular shape configured to be held or received by the circular frame 108 of FIG. 2B. Though not shown, the filter bodies 110 with rectangular windows can also have symmetrical or asymmetrical elliptical shapes to fit the frames of FIGS. 2C and 2D. Other filter body shapes can be utilized without departing from the scope of the present disclosure.

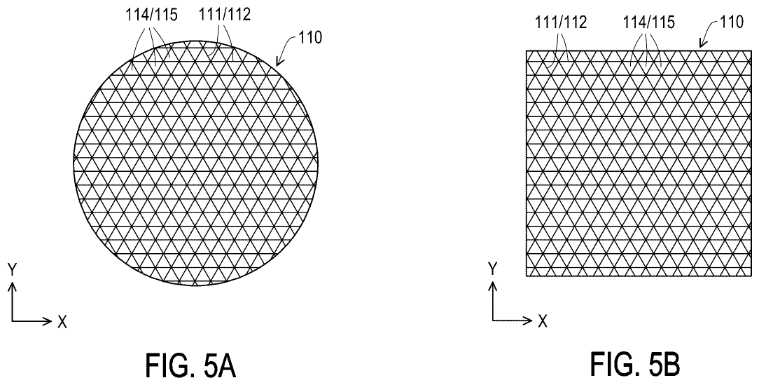

FIGS. 5A-5B illustrate filter bodies 110 having various shapes, in accordance with some embodiments. Each of the filter bodies 110 has a mesh 111 of a triangular shape. In other words, the mesh 111 defines cells 114 (or windows) having a triangular shape. In some embodiments, the triangles are equilateral triangles. Though not shown in FIGS. 5A-5B the cells 114 are filled with the filter material, as described previously. In some embodiments, the width of each triangular cell 114 is between 0.1 μm and 100 μm, though other dimensions can be utilized without departing from the scope of the present disclosure. The triangular pattern offers high tensile stress and rigidity. The triangular cells can help in disturbing loads uniformly.

In FIG. 5A, the filter body 110 has an overall rectangular shape configured to be held or received by the rectangular frame 108 of FIG. 2A. In FIG. 5B, the filter body 110 has an overall circular shape configured to be held or received by the circular frame 108 of FIG. 2B. Though not shown, the filter bodies 110 with triangular windows can also have symmetrical or asymmetrical elliptical shapes to fit the frames of FIGS. 2C and 2D. Other filter body shapes can be utilized without departing from the scope of the present disclosure.

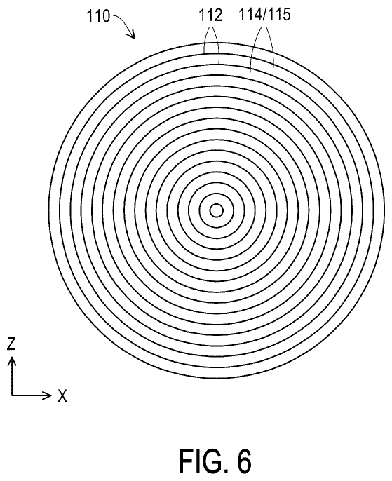

FIG. 6 illustrates a filter body 110 having an overall circular shape, in accordance with some embodiments. The filter body 110 includes a mesh 111 of wires 112, corresponding to a plurality of concentric circles each surrounding a central point. In some embodiments, the space between each adjacent pair of concentric circles of the mesh 111 is between 0.1 μm and 100 μm. Accordingly, the mesh 111 defines a plurality of concentric windows 114 filled with the filter material. In some embodiments, the circles of the mesh 111 are evenly spaced apart from each other. The mesh 111 of FIG. 6 can provide localized reinforcement in this particular useful for applications. The call for radial symmetry.

In some embodiments, the mesh 111 of a filter body 110 has a uniform distribution. Examples of such uniform distribution are shown in FIGS. 3A-3D, 4A-4B, 5A-5B, and 6. This can help ensure even mechanical properties across the entire surface of the filter body 110.

In some embodiments, the mesh 111 of a filter body 110 has a gradient distribution. In some embodiments, the gradient distribution includes wires that are spaced further apart in some locations than in others. For example, if a beam of the light of the optical system is an inner portion of a filter body 110, then the spacing of the wires (i.e., cell widths) may be greater in the inner portion of the filter body than in outer portions of the filter body 110. In the outer portions of the filter body 110 that are not expected to receive the like, the wires 112 may be closer together to enhance mechanical strength at the outer portions. In some embodiments, the wires 112 are laterally thicker at locations where greater mechanical strength is called for and are laterally thinner where more light transmission is called for. Accordingly, in some embodiments, the mesh 111 includes localized reinforcement that concentrates wires in areas that will experience higher stress or call for additional support.

In some embodiments, in a circular filter body 110, in an inner portion of the filter body, the width of the cells 114 is between 45 and 55 μm and the width of the wires 112 is less than 10 μm. In some embodiments, an outer portion of the filter body 110, the windows are less than 100 μm and the mesh wire 112 has a thickness greater than 30 μm 112.

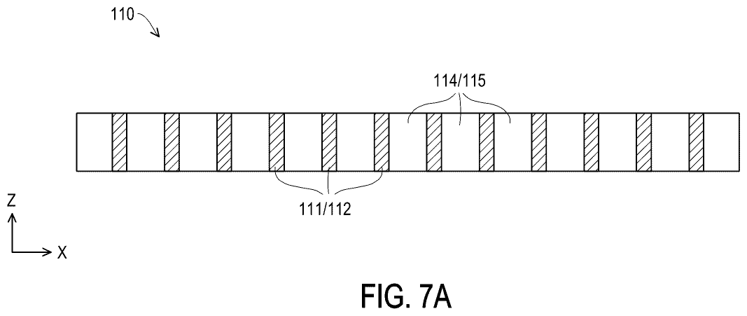

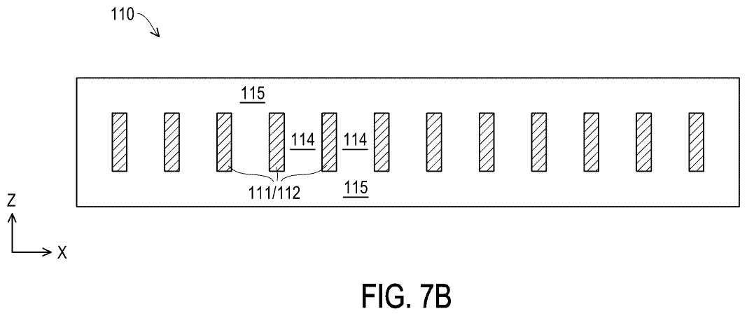

FIG. 7A is a cross-sectional view of a filter body 110, in accordance with some embodiments. The filter body 110 includes a mesh 111 made up of wires 112. The wires 112 are evenly spaced apart from each other throughout the filter body 110. The wires 112 define cells 114 filled with filter material 115.

In FIG. 7A, the wires 112 extend vertically from a bottom surface to a top surface (or front surface to back surface when installed in an application). In these examples, the top and bottom surfaces of the wires 112 are coplanar with the top and bottom surfaces of the filter material 115.

FIG. 7B is a cross-sectional view of a filter body 110, in accordance with some embodiments. The filter body 110 includes a mesh 111 made up of wires 112. The wires 112 are evenly spaced apart from each other throughout the filter body 110. The wires 112 define cells 114 filled with filter material 115.

In FIG. 7B, the filter material 115 fills the cells 114, as in FIG. 7A. However, in FIG. 7B, the filter material 115 also covers the top and bottom surfaces of the wires 112. In some embodiments, the filter material may cover only the top surface of the wires 112 or only the bottom surface of the wires 112. Various configurations can be utilized without departing from the scope of the present disclosure.

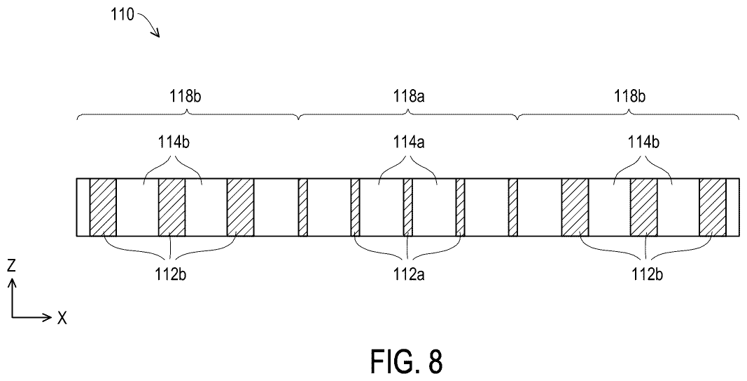

FIG. 8 is a cross-sectional view of a filter body 110, in accordance with some embodiments. The filter body 110 of FIG. 8 is substantially similar to the filter body 110 of FIG. 7A. FIG. 8 illustrates a central portion 118a of the filter body 110 and a peripheral portion 118b of the filter body 110. The central portion 118a corresponds to a portion of the filter body 110 expected to receive the light to be filtered. The peripheral portion 118b corresponds to a portion of the filter body 110 that is not expected to receive the lights to be filtered. Accordingly, the expected light beam is a smaller diameter than the width of the filter body 110. The wires 112a at the central portion 118a are laterally thinner than the wires 118b of the peripheral portion 118b. Correspondingly, the cells 114a in the central portion 118a are wider than the cells 114b in the peripheral portion 118b.

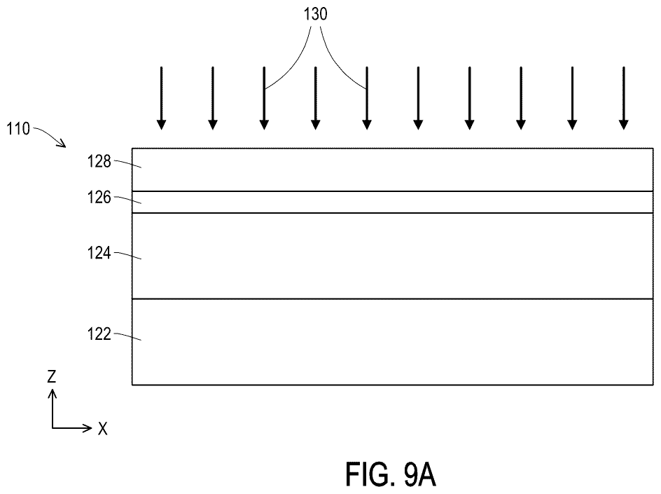

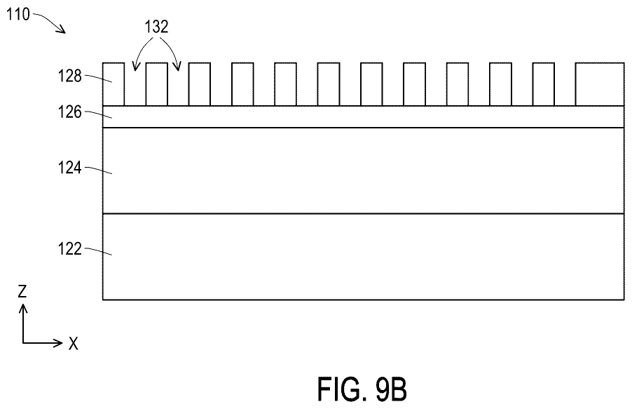

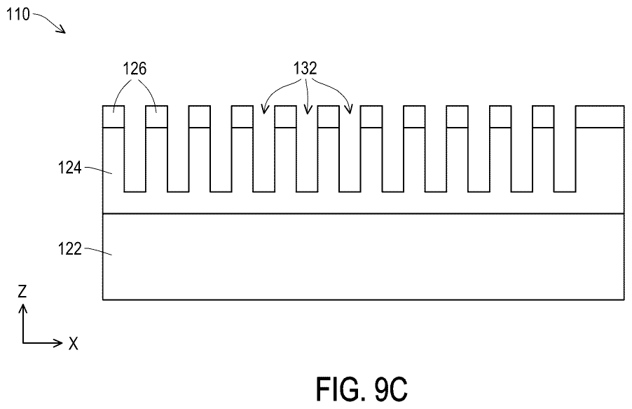

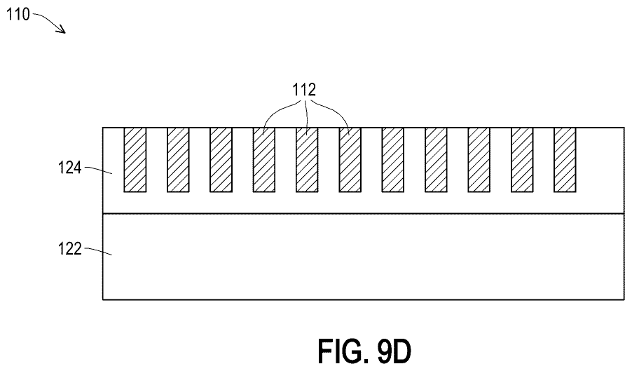

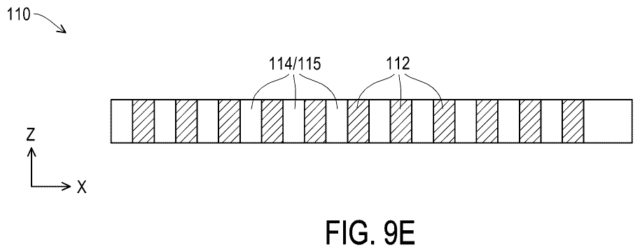

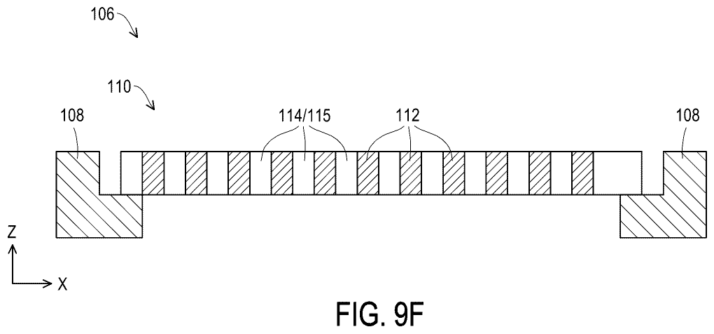

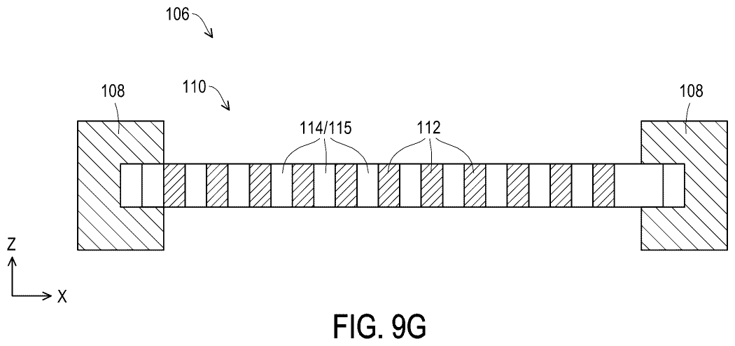

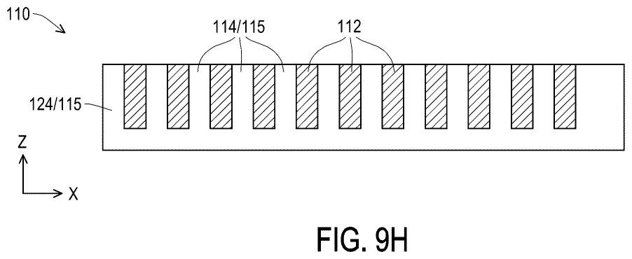

FIGS. 9A-9H are cross-sectional views of a filter body at various stages of manufacture, in accordance with some embodiments. At the stage of processing shown in FIG. 9A, the filter body 110 includes a substrate 122 and layer of material 124 on the substrate.

In some embodiments, the substrate 122 includes a semiconductor material. For example, the filter body 110 may be processed from a semiconductor wafer. The semiconductor wafer includes the substrate 122. Alternatively, the filter body 110 may be processed from a substrate or material other than a semiconductor wafer. In some embodiments, the substrate 122 includes a dielectric material such as silicon oxide, silicon nitride, or other suitable dielectric materials.

In some embodiments, the layer of material 124 corresponds to the filter material 115. In these cases, as will be set forth in more detail below, the layer of material 124 will be patterned with trenches in accordance with the desired pattern of the mesh 111. The material of the wires 112 will then be deposited in the trenches in the layer of material 124. In this way, the wires 112 are embedded in the filter material 115. Accordingly, the layer of material 124 can include the various materials described previously for the filter material, or other suitable materials.

In some embodiments, the layer of material 124 corresponds to the material of the wires 112. In these cases, the layer of material 124 will be patterned with trenches in accordance with the pattern of the mesh 111. The trenches corresponds to the position of the cells 114 or windows. The filter material is then deposited in the trenches. Accordingly, the layer of material 124 can include the various materials described previously for the wires 112, or other suitable materials.

In some embodiments, the layer of material 124 includes a material other than the material of the filter material 115 or the wires 112. Accordingly, the layer of material 124 can include or other types of material.

A hard mask layer 126 is positioned on the layer of material 124, in accordance with some embodiments. The hard mask layer 126 includes a dielectric material that will be patterned and use of the hard mask to pattern the layer of material 124. The hard mask layer 126 can include SiN, SiC, SiCN, SiCON, SiCO, or other suitable materials.

A layer of lithography resist 128 is positioned on the hard mask layer 126, in accordance with some embodiments. In the example FIG. 9A, the lithography resist 128 includes e-beam resist susceptible to being patterned by an electron-beam in an e-beam lithography process. Alternatively, the lithography resist 128 can include a photoresist to be utilized in a photolithography process for patterning the layer of material 124.

In FIG. 9A, a patterned electron-beam 130 irradiates the layer of lithography resist 128. The pattern of the electron-beam 130, is selected in accordance with the desired pattern of the mesh 111.

In FIG. 9B, trenches 132 have been formed in the lithography resist 128, in accordance with some embodiments. The trenches 132 have the pattern of the mesh 111.

In FIG. 9C, the trenches 132 have been extended through the hard mask layer 126 into the layer of material 124. This can be accomplished by an etching process, such as a wet etch, a dry etch, or other processes. In some embodiments, the trenches 132 are formed directly via e-beam lithography.

In FIG. 9D, the wires 112 have been formed in the trenches 130. The layer of material 124, in accordance with some embodiments. The material of the wires 112 can be deposited in the trenches by sputtering, e-beam evaporation, physical vapor deposition (PVD), chemical vapor deposition (CVD), or other suitable deposition processes. The material of the wires 112 is selected from those described previously, or from other suitable materials. After deposition of the material of the wires 112, the hard mask layer 126 is removed. In some embodiments, a chemical mechanical planarization (CMP) process is performed to remove the hard mask layer 126 and to planarize the top surface of the filter body 110.

In FIG. 9E, a backside process has been performed to remove the substrate 122, in accordance with some embodiments. The backside process can include one or more of a grinding process, a CMP process, or other suitable processes. The backside processes also expose the bottom surfaces of the wires 112. The filter body 110 is substantially complete, including wires 112 and cells 114 of filter material 115.

Alternatively, as shown in FIG. 9H, a portion of the filter material 115 remains below the wires 112. In this case, the backside process removes the substrate 122 without removing the layer of material 124. Although not shown in FIG. 9H, additionally, a subsequent deposition of the filter material 115 can be performed to cover the top surfaces of the wires 112 with the filter material 115, as shown in FIG. 7B.

Various other processes can be utilized to form the filter body 110 including the mesh 111. For example, photolithography processes, electric spinning, 3D printing, PVD, CVD, and other processes can be utilized to form the filter body 110 including the mesh 111.

In FIG. 9F, the filter body 110 has been coupled to a frame 108 to form the filter assembly 106, in accordance with some embodiments. In FIG. 9F, the bottom edges of the filter body 110 are positioned on an L-shaped frame 108. However, other configurations of the frame and filter body can be utilized for the filter assembly 106, without departing from the scope of the present disclosure.

In FIG. 9G, the filter body 110 is coupled to a frame 108 to form the filter assembly 106, in accordance with some embodiments. In FIG. 9G, the frame 108 includes a C-shape that holds the top and bottom surfaces of the edge of the filter body 110. Other shapes of the frame 108 can be utilized without departing from the scope of the present disclosure.

FIG. 9H illustrates a filter body 110, in accordance with some embodiments. In FIG. 9H, a portion of the filter material 115 remains below the wires 112. In this case, the backside process removes the substrate 122 without removing the layer of material 124. Although not shown in FIG. 9H, additionally, a subsequent deposition of the filter material 115 can be performed to cover the top surfaces of the wires 112 with the filter material 115, as shown in FIG. 7B.

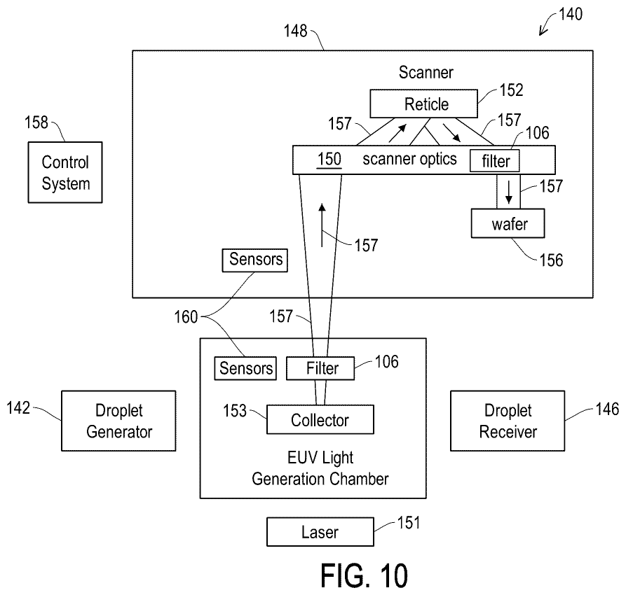

FIG. 10 is a block diagram of an EUV photolithography system 140, according to some embodiments. The EUV photolithography system 140 of FIG. 10 is one example of an optical system 100 of FIG. 1. The components of the EUV photolithography system 140 cooperate to generate EUV light and perform photolithography processes. As will be set forth in more detail below, one or more filter assemblies 106 are implemented in the EUV photolithography system 140. As used herein, the terms “EUV light” and “EUV radiation” can be used interchangeably.

The EUV photolithography system 140 includes a droplet generator 142, an EUV light generation chamber 144, a droplet receiver 146, a scanner 148, and a laser 151. The droplet generator 142 outputs droplets into the EUV light generation chamber 144. The laser 151 irradiates the droplets with pulses of laser light within the EUV light generation chamber 144. The irradiated droplets emit EUV light 157. The EUV light 157 is collected by a collector 153 and reflected toward the scanner 148. The scanner 148 conditions the EUV light 157, reflects the EUV light 157 off of a reticle 152 including a mask pattern, and focuses the EUV light 157 onto the wafer 156. The EUV light 157 patterns a layer on the wafer 156 in accordance with a pattern of the reticle 152. Each of these processes is described in more detail below.

The droplet generator 142 generates and outputs a stream of droplets. The droplets can include tin, though droplets of other material can be utilized without departing from the scope of the present disclosure. The droplets move at a high rate of speed toward the droplet receiver 146. The droplets have an average velocity between 60 m/s to 200 m/s. The droplets have a diameter between 14 μm and 200 μm. The generator may output between 1400 and 140000 droplets per second. The droplet generator 142 can generate droplets having different initial velocities and diameters than those described above without departing from the scope of the present disclosure.

In some embodiments, the EUV light generation chamber 144 is a laser produced plasma (LPP) EUV light generation system. As the droplets travel through the EUV light generation chamber 144 between the droplet generator 142 and the droplet receiver 146, the droplets are irradiated by the laser 151. When a droplet is irradiated by the laser 151, the energy from the laser 151 causes the droplet to form a plasma. The plasmatized droplets generate EUV light 157. This EUV light 157 is collected by the collector 153 and passed to the scanner 148 and then on to the wafer 156.

In some embodiments, the laser 151 is positioned external to the EUV light generation chamber 144. During operation, the laser 151 outputs pulses of laser light into the EUV light generation chamber 144. The pulses of laser light are focused on a point through which the droplets pass on their way from the droplet generator 142 to the droplet receiver 146. Each pulse of laser light is received by a droplet. When the droplet receives the pulse of laser light, the energy from the laser pulse generates a high-energy plasma from the droplet. The high-energy plasma outputs EUV light 157.

In some embodiments, the laser 151 irradiates the droplet with two pulses. A first pulse causes the droplet to flatten into a disk-like shape. The second pulse causes the droplet to form a high temperature plasma. The second pulse is significantly more powerful than the first pulse. The laser 151 and the droplet generator 142 are calibrated so that the laser emits pairs of pulses such that the droplet is irradiated with a pair of pulses. The laser can irradiate droplets in a manner other than described above without departing from the scope of the present disclosure. For example, the laser 151 may irradiate each droplet with a single pulse or with more pulses than two. In some embodiments, there are two separate lasers. A first laser delivers the flattening pulse. A second laser delivers the plasmatizing pulse.

In some embodiments, the light output by the droplets scatters randomly in many directions. The photolithography system 140 utilizes the collector 153 to collect the scattered EUV light 157 from the plasma and direct or output the EUV light 157 toward the scanner 148.

The plasma generated within the chamber 144 outputs EUV light with a wavelength of approximately 13.5 nm. This wavelength of light is utilized for the EUV photolithography processes. However, other wavelengths of light may also be generated by the plasma within the chamber 144.

A filter assembly 106 positioned within the chamber 144, in the expected path of travel of the EUV light 157. The filter assembly 106 includes the frame 108 and the filter body 110, as described previously. Furthermore, the filter body 110 includes the mesh 111 of wires 112 and the filter material 115, as described previously. As the light from the plasma travels through the filter assembly 106, the filter body 110 of the filter assembly 106 passes EUV light having the desired wavelength of ~13.5 nm. The filter body 110 filters out light outside the desired passband. This helps to ensure that the photolithography processes are properly performed. Furthermore, in some embodiments, the filter assembly 106 also blocks debris particles resulting from the plasmatized droplets from passing into the scanner 148. Because the filter assembly includes the frame 108 and the mesh 111, the filter body is robust and less susceptible to being damaged.

The scanner 148 includes scanner optics 150. The scanner optics 150 include a series of optical conditioning devices to direct the EUV light 157 to the reticle. The scanner optics 150 may include refractive optics such as a lens or a lens system having multiple lenses (zone plates). The scanner optics 150 may include reflective optics, such as a single mirror or a mirror system having multiple mirrors. The scanner optics 150 direct the EUV light 157 from the EUV light generation chamber 144 to a reticle 152.

The EUV light 157 reflects off of the reticle 152 back toward further optical features of the scanner optics 150. In some embodiments, the scanner optics 150 include a projection optics box. The projection optics box may have refractive optics, reflective optics, or combination of refractive and reflective optics. The projection optics box may include a magnification less than 1, thereby reducing the patterned image included in the EUV light 157 reflected from the reticle. The projection optics box directs the EUV light 157 onto the wafer 156, for example, a semiconductor wafer.

A filter assembly 106 positioned in the scanner 148 among the scanner optics 150, in accordance with some embodiments. The filter assembly 106 is positioned in the expected path of travel of the EUV light 157. The filter assembly 106 includes the frame 108 and the filter body 110, as described previously. Furthermore, the filter body 110 includes the mesh 111 of wires 112 and the filter material 115. In some cases, a plasma gas may form within the scanner 148. The plasma gas may output light in wavelengths outside of the expected range of the EUV light 157. The frame 108, the filter body 110, and the mesh 111 filter out the undesired wavelengths of light. Because the filter assembly includes the frame 108 and the mesh 111, the filter body is robust and less susceptible to being damaged.

The EUV light 157 includes a pattern from the reticle. In particular, the reticle includes the pattern to be defined in the wafer 156. After the EUV light 157 reflects off of the reticle, the EUV light 157 contains the pattern of the reticle. A layer of photoresist typically covers the target during extreme ultraviolet photolithography irradiation. The photoresist assists in patterning a surface of the semiconductor wafer in accordance with the pattern of the reticle.

The control system 158 is communicatively coupled to the droplet generator 142 and the laser 151. The control system 158 can control the operation of the droplet generator 142 and the laser 151. The control system 158 can adjust operating parameters of the droplet generator 142 and the laser 151.

In some embodiments, the EUV photolithography system 140 includes a plurality of sensors 160. Some of the sensors 160 are positioned within the EUV light generation chamber 144 and some are positioned within the scanner 148. In some embodiments, a first pressure sensor is positioned in the EUV light generation chamber 144 and the second pressure sensor is positioned in the scanner 148. The pressure sensors generate pressure signals indicating the pressure differential between the scanner 148 and the EUV light generation chamber 144. If the pressure differential is less than an expected threshold, this can indicate a failure in the filter.

In some embodiments, the sensors 160 include a light intensity sensor that senses the intensity of light at a selected position within the scanner on 48. If the intensity is less than a threshold intensity, this can indicate a failure of the filter assembly 160. Alternatively, this can indicate that one or more of the lenses were mirrors among the scanner optics 150 is out of focus.

In some embodiments, the control system 158 is communicatively coupled to the sensors 160. If the sensor signals indicate the pressure falls, a life intensity fault, or focal position fault, then the control system can take steps to address the problem. In some cases, the control system 158 automatically shuts down an EUV photolithography process is sensor signals indicate that a filter assembly 106 has failed. In some cases, the control system 158 outputs a signal or alert indicating that the filter assembly is failed. Where multiple filter assemblies 106 are present, the control system 115 can indicate which of the filter assemblies has failed. If the sensor signals indicate a focal point misalignment, then the control system 158 can control a motor to adjust a position of one or more lenses were mirrors within the scanner optics 150. Various other types of sensors and control measures can be utilized without departing from the scope of the present disclosure.

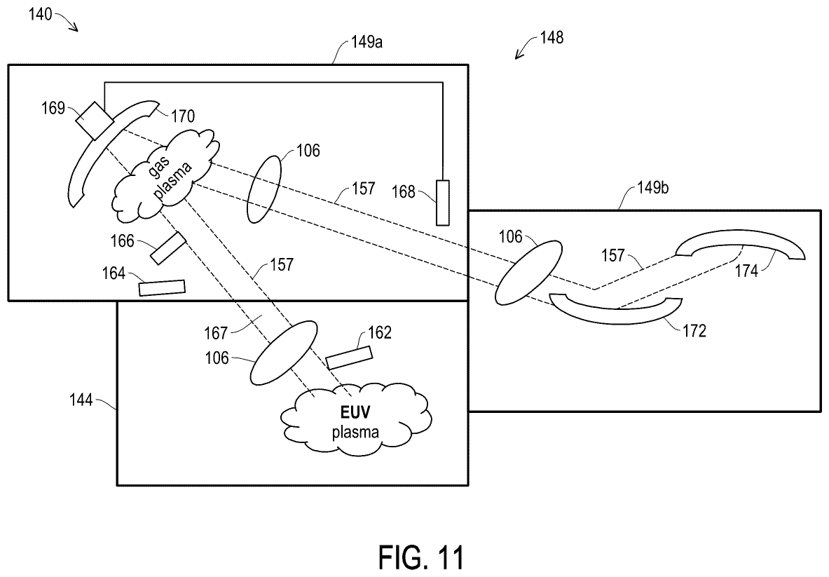

FIG. 11 is a simplified illustration of a portion of an EUV photolithography system 140, in accordance with some embodiments. The simplified EUV photolithography system 140 of FIG. 11 can include components described in relation to FIG. 10.

In FIG. 11, a filter assembly 106 is positioned in a path of travel of the EUV light 157 within the EUV light generation chamber 144. A first pressure sensor 162 is also positioned in the EUV light generation chamber 144. Some embodiments, the filter assembly 106 is positioned to prevent fluid communication between the EUV light generation chamber 144 and the first chamber 149a of the scanner 148. The first pressure sensor 162 senses the pressure within the EUV light generation chamber 144.

In FIG. 11, the scanner optics include a first mirror 170 in the first chamber 149a of the scanner 148. The scanner optics include a mirror 172 and a mirror 174 within a second chamber 149b of the scanner 148. For simplicity, FIG. 11 does not illustrate additional scanner optics or the reticle of the EUV photolithography system. The various mirrors direct the path of travel of the EUV light 157 through the scanner 148.

In FIG. 11, a second pressure sensor 164 is positioned in the chamber 149a, in accordance with some embodiments. The pressure sensors 162 and 164 each generate pressure signals that indicate a pressure differential between the EUV light generation chamber 144 and the first chamber 149a of the scanner 148. As described previously, if the pressure differential is less than a threshold, this can indicate a fault in the filter assembly 106, or in other components of the system 140.

In FIG. 11, an optical sensor 166 is positioned adjacent to the path of travel of the EUV light 157 in the first chamber 149a. The optical sensor 166 senses and intensity of the EUV light 157. If the intensity of the EUV light 157 is less than a threshold, this can indicate a fault in the filter 106. For example, this can indicate that the filter assembly 106 is broken, discovered in debris, or is otherwise not passing enough EUV light.

In FIG. 11, an optical sensor 168 is positioned adjacent to the path of travel of the EUV light 157 in the first chamber 149a. The optical sensor 168 senses an intensity of the EUV light 157 at a particular location. If the intensity of the EUV light 157 is less than a threshold, this can indicate that the mere 170 is out of position. The control system 158 can then control a motor 169 to adjust the position of the mere 170. In FIG. 11, a filter assembly 106 is positioned within the first chamber 149a of the scanner 148. A filter assembly 106 is also positioned within the second chamber 149b of the scanner 148.

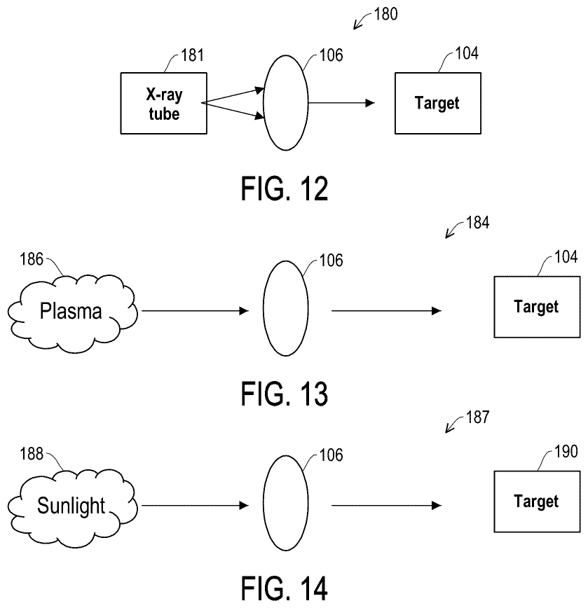

FIG. 12 is a simplified block diagram of an x-ray system 180, in accordance with some embodiments. The x-ray system 180 is one example of an optical system 100 of FIG. 1. The x-ray system 180 includes an x-ray tube 181 that generates x-rays. The x-ray system 180 includes a filter assembly 106 that filters x-rays, as described previously. In some embodiments, the x-ray system 180 is a medical imaging system. In some embodiments, the x-ray system 180 is a material structure imaging system. Accordingly, the target 104 can include a person or a material, in accordance with some embodiments.

FIG. 13 is a simplified block diagram of an optical system 184, in accordance with some embodiments. The optical system 184 includes a plasma 186 that generates light. The filter assembly 106 filters out undesired wavelengths from the light and passes the desired wavelengths to the target 104. The desired wavelengths can include ultraviolet, visible, or infrared light of a selected band.

FIG. 14 is a simplified block diagram of an optical system 187, in accordance with some embodiments. The optical system 187 includes a, a light source 188 that generates natural light, such as sunlight. The filter assembly 106 filters out undesired wavelengths from the sunlight and passes the desired wavelengths to a photodiode 190, or other type of target. The photodiode 190 converts the sunlight to electricity. Other types of optical systems can be utilized without departing from the scope of the present disclosure.

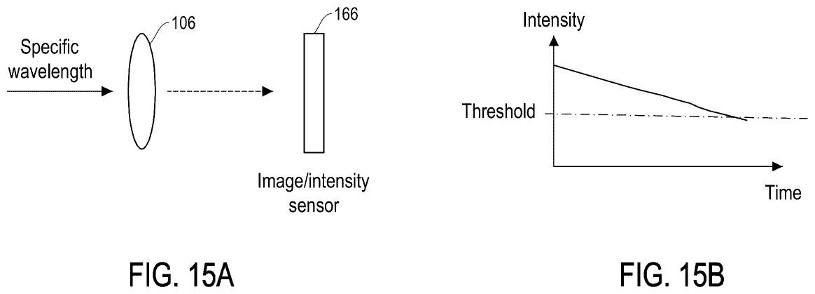

FIG. 15A is a simplified illustration of light passing through a filter assembly 106 to an optical sensor 166, in accordance with some embodiments. The optical sensor 166 senses the intensity of the light. FIG. 15B is a graph illustrating the intensity of the light over time. As the filter 106 is used over time, the filter 106 may degrade and pass less and less light. If the intensity drops below the threshold, this can indicate a fault in the filter 106.

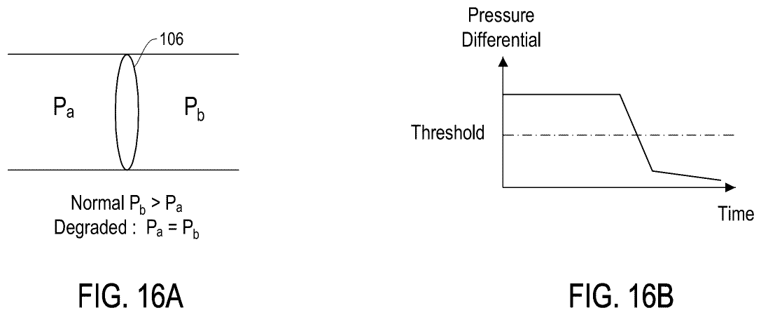

FIG. 16A is a simplified illustration of a filter 106 positioned between 2 portions of an optical system, in accordance with some embodiments. Pressure sensors measure the pressure Pa in a first portion of the system and the pressure Pb in a second portion of the system. FIG. 16B illustrates the pressure differential. If the pressure differential drops below a threshold, this can indicate a degraded filter 106.

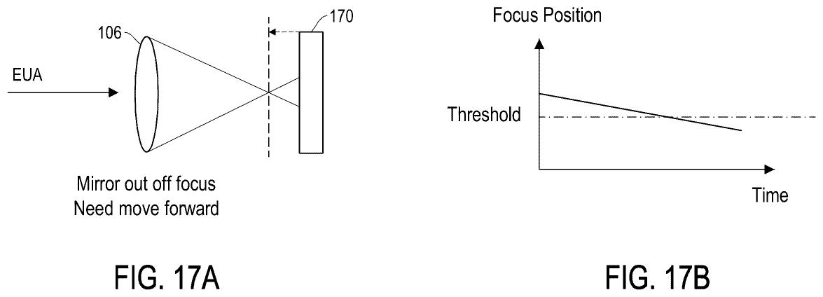

FIG. 17A is a simplified illustration of light passing through a filter assembly 106 to an optical sensor 170, in accordance with some embodiments. The light may pass from a mirror to the filter 106. If the intensity of the light is less than a threshold, this can indicate that the mirror is out of position and need to be moved. As described previously, a control system can automatically move the mirror. FIG. 17B illustrates the focus position over time.

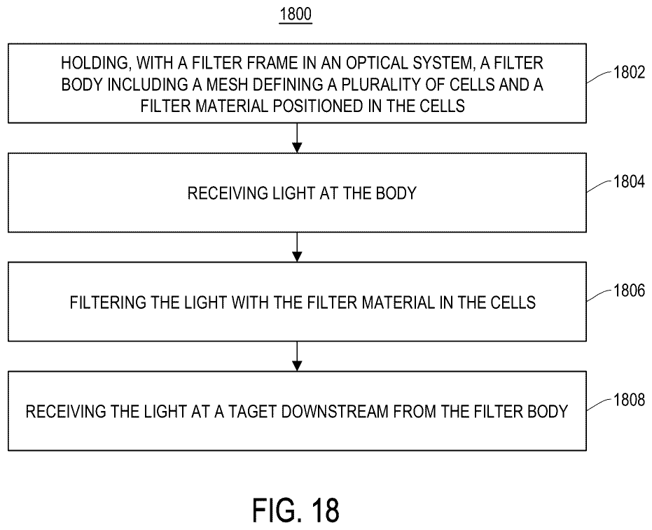

FIG. 18 is a flow diagram of a method 1800 for operating an optical system, in accordance with some embodiments. The method 1800 can utilize processes, components, and systems described in relation to the foregoing figures. At 1802, the method 1800 includes holding, with a filter frame in an optical system, a filter body including a mesh defining a plurality of cells and a filter material positioned in the cells. One example of a filter frame is the filter frame 108 of FIG. 1. One example of an optical system is the optical system 100 of FIG. 1. One example of a filter body is the filter body 110 of FIG. 1. One example of a mesh is the mesh one 11 of FIG. 1. Of cells are the cells 114 of FIG. 7A. One example of filter material as the filter material 115 of FIG. 7A. At 1804, the method 1800 includes receiving light at the filter body. At 1806, the method 1800 includes filtering the light with the filter material in the cells. At 1808, the method 1800 includes receiving the light at a target downstream from the filter body. One example of a target is the target 104 of FIG. 1.

Embodiments of the present disclosure provide an optical filter assembly for optical systems. The optical filter assembly includes an optical filter body with a mesh including wire portions defining cells of material transparent to a desired range of wavelengths of light for the optical system. The filter body and corresponding mesh can be formed via thin film process technologies including e-beam lithography or photolithography on a substrate and corresponding material deposition, and etching processes. Due to the presence of the mesh portions, the filter body is much more robust than filter structures that do not include such a mesh. Furthermore, the presence of the mesh enables the optical filter body to be very thin while maintaining high durability with respect to tensile forces, compressive forces, impact forces, and other types of forces or environmental conditions that could otherwise damage such a thin optical filter body. The filter assembly includes a frame of a highly robust material. The frame holds the filter within an optical system. The frame further adds to the durability and strength of the filter assembly.

In some embodiments, a system includes a light source configured to generate light, a target configured to receive the light, and a first filter assembly positioned to filter the light upstream from the target. The filter assembly includes a filter body including a mesh defining a plurality of cells, a filter material positioned in the cells and configured to pass the light from the light source to the target, and a filter frame configured to hold the filter body.

In some embodiments, a device includes an optical filter body. The optical filter body includes a filter material configured to receive light and to pass filtered light, a plurality of trenches in the filter material, and a mesh including a mesh material in the trenches defining a plurality of cells of the filter material. The device includes a filter frame configured to hold the filter body.

In some embodiments, a method includes holding, with a filter frame in an optical system, a filter body including a mesh defining a plurality of cells and a filter material positioned in the cells. The method includes receiving light at the filter body, filtering the light with the filter material in the cells, and receiving the light at a target downstream from the filter body.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A system, comprising:
a light source configured to generate light;
a target configured to receive the light; and
a first filter assembly positioned to filter the light upstream from the target and including:
a filter body including a mesh defining a plurality of cells;
a filter material positioned in the cells and configured to pass the light from the light source to the target; and
a filter frame configured to hold the filter body.

2. The system of claim 1, wherein the light source is a photolithography light generation chamber, the system comprising a scanner coupled to the photolithography light generation chamber, wherein the first filter is in either the scanner or the photolithography light generation chamber.

3. The system of claim 2, comprising:
a first pressure sensor in the photolithography light generation chamber and configured to generate first pressure signals;
a second pressure sensor in the scanner and configured to generate second pressure signals; and
a control system configured to detect a failure of the first filter assembly based on the first and second pressure signals.

4. The system of claim 2, comprising:
a light intensity sensor in the scanner downstream from the first filter assembly and configured to generate intensity signals indicative of an intensity of the light; and
a control system configured to detect a failure of the first filter assembly based on the intensity signals.

5. The system of claim 2, comprising:
a mirror in the scanner upstream from the first filter assembly;
a light intensity sensor in the scanner downstream from the first filter assembly and configured to generate intensity signals indicative of an intensity of the light; and
a control system configured to adjust a position of the mirror responsive to the intensity signals.

6. The system of claim 2, comprising a second filter assembly in the photolithography light generation chamber, wherein the first filter assembly is in the scanner.

7. The system of claim 1, wherein the mesh is embedded in the filter material.

8. The system of claim 1, wherein the filter body is less than 1μm in thickness.

9. The system of claim 1, wherein the cells include a honeycomb shape.

10. The system of claim 1, wherein the cells are triangular, rectangular, or circular.

11. The system of claim 1, wherein the filter frame is circular, rectangular, or elliptical and has a same shape as the filter body.

12. A device, comprising:
an optical filter body including:
a filter material configured to receive light and to pass filtered light;
a plurality of trenches in the filter material;
a mesh including a mesh material in the trenches defining a plurality of cells of the filter material; and
a filter frame configured to hold the filter body.

13. The device of claim 12, wherein the filter frame is stainless steel or aluminum.

14. The device of claim 12, wherein the filter material covers all surfaces of the mesh material.

15. The device of claim 12, wherein the cells are wider in a central region of the filter body than at a peripheral region of the filter body.

16. The device of claim 12, wherein a surface of the mesh material is coplanar with a surface of the filter material.

17. A method, comprising:
holding, with a filter frame in an optical system, a filter body including a mesh defining a plurality of cells and a filter material positioned in the cells;
receiving light at the filter body;
filtering the light with the filter material in the cells; and
receiving the light at a target downstream from the filter body.

18. The method of claim 17, wherein the optical system is an x-ray system.

19. The method of claim 17, wherein the optical system is a photolithography system, the method comprising:
sensing an intensity of the light downstream from the filter body; and
sensing a failure of the filter body based on the intensity of the light.

20. The method of claim 17, comprising generating electricity with the target.
